(19) United States
(12) Patent Application Publication
(10) Pub. No.: US 2007/0284614 A1
(43) Pub. Date: Dec. 13, 2007

(54) Ohmic contacts for semiconductor devices

(76) Inventors: Ilesanmi Adesida, Champaign, IL (US); Weifeng Zhao, San Ramon, CA (US); Liang Wang, Urbana, IL (US)

Correspondence Address: MARTIN NOVACK, 16355 VINTAGE OAKS LANE, DELRAY BEACH, FL, 33484, US

(21) Appl. No.: 11/805,854

(22) Filed: May 24, 2007

Related U.S. Application Data
(60) Provisional application No. 60/808,478, filed on May 24, 2006.
(60) Provisional application No. 60/808,440, filed on May 24, 2006.

(51) Int. Cl. H01L 29/739; H01L 21/3205

(52) U.S. Cl. 257/194; 257/E29.246; 438/590

(57) ABSTRACT

A method for making a high electron mobility field-effect transistor device, including the following steps: providing a layered semiconductor structure that includes an InGaAs channel layer and at least two layers over the channel layer, the at least two layers including a layer of InAlAs, a portion of which has an InGaAs cap layer deposited thereon; depositing spaced apart source and drain ohmic contacts on the InGaAs cap layer, the source and drain contacts comprising Ge/Ag/Ni contacts; and depositing a gate contact, between the source and drain contacts, on the InAlAs layer.

### RELATED APPLICATIONS

Priority is claimed from U.S. Provisional Patent Application No. 60/808,478, filed May 24, 2006, and U.S. Provisional Patent Application No. 60/808,440, filed May 24, 2006, and both said U.S. Provisional Patent Applications are incorporated herein by reference. The subject matter of the present Application is related to subject matter disclosed in copending U.S. Patent Application Ser. No. ______ (File UI-TF-06075), filed of even date herewith, and assigned to the same assignee as the present Application.

### GOVERNMENT RIGHTS

This invention was made with Government support under Contract Number ANI-0121662 awarded by the National Science Foundation (NSF) and Contract Number N00014-01-1-1000 awarded by Office of Naval Research (ONR). The Government has certain rights in the invention.

### FIELD OF THE INVENTION

This invention relates to the field of semiconductor devices and methods and, more particularly, to ohmic contacts for semiconductor devices, and fabrication techniques for same.

### BACKGROUND OF THE INVENTION

The InAlAs/InGaAs/InP high electron mobility transistors “HEMTs” or heterostructure field effect transistors (“HFETs”), or the metamorphic InAlAs/InGaAs/GaAs variant, is considered to be one of the most promising devices for high speed digital circuits, millimeter and submillimeter applications due to its superior high frequency and low noise capabilities.

The realization of low resistance and stable ohmic contacts play an important role toward the achievement of excellent performance and reliable operation of HEMTs. The conventional annealed Au—Ge—Ni ohmic contact metallization scheme used in GaAs technologies has been widely utilized for InP-based HEMTs. However, the annealing temperature required to obtain the minimum contact resistance in the InAlAs/InGaAs system is relatively low (i.e., temperatures below 300° C.). This becomes a problem when devices are subjected to similar or higher temperatures during device fabrication or operation after the ohmic contact is formed. When this occurs, the contact resistance of Au—Ge—Ni ohmic contacts on InAlAs/InGaAs HEMTs can degrade rapidly and be irreversible, thus causing reliability concerns (see Mammann, M., Leuther, A., Benkhelifa, F., Feltgen, T., and Jantz, W., Phys. Stat. Sol. (a), 2003, 195, (1), pp. 81-86; Alamo, J. A. del, and Villanueva, A. A., IEDM, 2004, pp. 41.1.1-41.1.4). This limitation is observed during accelerated lifetime tests that are usually conducted at temperatures above 215° C. In addition, the interest in achieving enchancement-mode operation (positive threshold voltage) for InAlAs/InGaAs HEMTs can require thermal treatment of the gate (usually Pt, at temperatures around 250° C.) to increase Schottky barrier height (see Chen, K. J., Enoki, T., Maezawa, K., Arai, K., and Yamamoto, M., IEEE Trans. on Electron Devices, 1996, 43, (2), pp. 252-257; Mahajan, A., Arafa, M. Fay, P., Caneau, C. and Adesida, I., IEEE Trans. on Electron Devices, 1998, 45, (12), pp. 2422-2429). Deposition of SiNₓ by plasma-enhanced deposition for device passivation can also involve high temperature (e.g. 250 to 300° C.).

Non-annealed ohmic contact metallizations based on refractory metals, such as WSi and Mo, have been proposed for thermally stable ohmic contacts for InP HEMTs (see Yoshida, N., Yamamoto, Y., Takano, H., Sonoda, T., Takamiya, S., and Mitsui, S., Jpn. J. Appl. Phys., 1994, 33, Part 1, (6A), pp. 3373-3376; Onda, K., Fujihara, A., Mizuki, E., Hori, Y., Miyamoto, H., Samoto, N., and Kuzuhara, M., IEEE MTT-S Digest, 1994, pp. 261-264). However, such contacts usually require a thick highly doped InGaAs cap layer to realize acceptable contact resistances. Thick cap layers result in significantly large lateral etching during formation of the gate recess that can cause dispersion, thus degrading the device performance. One of the objects hereof is to address these limitations on forming low resistance ohmic contacts for HEMTs and other devices.

The presence of Au has been shown to be responsible for the unstable properties of annealed Au—Ge—Ni ohmic contacts on GaAs-based devices (see Y. C. Shih, M. Murakami, E. L. Wilkie, and A. C. Callegari, J. Appl. Phys. 62, 582 1987), Therefore, metallizations without Au, such as Pd/Ge, Ni/Ge, and Ge/Ag, have been developed for GaAs-based devices to realize better thermal stability (see E. D. Marshall, B. Zhang, L. C. Wang, P. F. Jiao, W. X. Chen, T. Sawada, S. S. Lau, K. L. Kavanagh, and T. F. Kuech, J. Appl. Phys. 62, 942, 1987; K. Tanahashi, H. J. Takata, A. Otuki, and M. Murakami, J. Appl. Phys. 72, 4183, 1992; and V. Chabasseur-Molyneux, J. E. F. Frost, M. J. Tribble, M. P. Grimshaw, D. A. Ritchie, A. C. Churchill, G. A. C. Jones, M. Pepper, and J. H. Burroughes, J. Appl. Phys. 74, 5883, 1993).

It is among the objects of the present invention to provide improved ohmic contacts and techniques for fabrication of same which overcome problems and limitations of prior art approaches, including those summarized above. It is also among the objects of the present invention to provide improved field effect devices and HEMTs, and methods for making same.

### SUMMARY OF THE INVENTION

A form of the invention is directed to a field-effect device that includes a layered semiconductor structure having a channel layer and at least one layer over the channel layer, said at least one layer including an InGaAs cap layer. Spaced apart source and drain ohmic contacts are disposed on the InGaAs cap layer, the source and drain contacts comprising silver-based contacts deposited on the InGaAs cap layer and a gate contact, between the source and drain contacts, is disposed on said at least one layer. In a preferred embodiment of this form of the invention, the silver-based source and drain ohmic contacts include deposited layers of germanium, silver, and nickel, thereby comprising Ge/Ag/Ni ohmic contacts. A metallic overlay, of high conductivity, for example Ti/Pt/Au, can be deposited over each of the Ge/Ag/Ni source and drain ohmic contacts.

Another form of the invention is directed to a method of forming an ohmic contact to a III-V semiconductor material, including the following steps: depositing a silver-based contact on the semiconductor material; and annealing the silver-based contact at a temperature greater than about 350° C. to form an ohmic contact on the semiconductor material. In an embodiment of this form of the invention, the silver-based contact is a Ge/Ag/Ni contact, and the semiconductor material is an indium-containing compound, such as InGaAs. In an embodiment of this form of the invention, the annealing is performed at a temperature of about 400° C.

A further form of the invention is directed to a high electron mobility field-effect transistor device, including: a layered semiconductor structure that includes an InGaAs channel layer and at least two layers over the channel layer, said at least two layers including a layer of InAlAs, a portion of which has an InGaAs cap layer deposited thereon. Spaced apart source and drain ohmic contacts are disposed on the InGaAs cap layer, the source and drain contacts comprising silver-based contacts deposited on the InGaAs cap layer. A gate contact, between the source and drain contacts, is disposed on the InAlAs layer. In a preferred embodiment of this form of the invention, the silver-based source and drain ohmic contacts include deposited layers of germanium, silver, and nickel, thereby comprising Ge/Ag/Ni ohmic contacts. A metallic overlay is deposited over each of the Ge/Ag/Ni source and drain ohmic contacts. In one embodiment, the metallic overlay comprises Ti/Pt/Au. Means can be provided for conventionally applying electrical potentials with respect to the drain, source, and gate contacts. Electrical potential, applied to the gate contact, controls current flow in the device between the drain and source.

In accordance with a further form of the invention, a method is provided for making a high electron mobility field-effect transistor device, including the following steps: providing a layered semiconductor structure that includes an InGaAs channel layer and at least two layers over the channel layer, said at least two layers including a layer of InAlAs, a portion of which has an InGaAs cap layer deposited thereon; depositing spaced apart source and drain ohmic contacts on the InGaAs cap layer, the source and drain contacts comprising Ge/Ag/Ni contacts; and depositing a gate contact, between the source and drain contacts, on the InAlAs layer. In a preferred embodiment of this form of the invention, the step of depositing Ge/Ag/Ni contacts on the InGaAs cap layer comprises annealing the Ge/Ag/Ni contacts at a temperature greater than about 350° C. to form an ohmic contact on the InGaAs cap layer. This embodiment further includes the steps of passivating the source and drain contacts prior to annealing, with Si₃N₄ or SiNₓ.

Further features and advantages of the invention will become more readily apparent from the following detailed description when taken in conjunction with the accompanying drawings.

### BRIEF DESCRIPTION OF THE DRAWINGS

FIG. 1 shows, in cross-section, an example of a high electron mobility transistor which can employ an embodiment of the invention.

FIG. 2 shows, in cross-section, the layer structure of a further example of high electron mobility transistors in which embodiments of the invention can be utilized.

FIG. 3 shows graphs of contact resistance as a function of annealing temperature for prior art contacts and for contacts in accordance with an embodiment of the invention.

FIG. 4 is a graph of sheet resistance as a function of annealing temperature for contacts in accordance with an embodiment of the invention.

FIG. 5a shows graphs of contact resistance and sheet resistance, as a function of annealing temperature, for contacts in accordance with an embodiment of the invention, without use of a SiNₓ passivation layer, and FIG. 5b shows contact resistance and sheet resistance of contacts in accordance with an embodiment of the invention with a 60 nm thick SiNₓ passivation layer.

FIG. 6 is a graph showing contact resistance as a function of annealing time, for contacts in accordance with an embodiment of the invention, annealed at different temperatures.

FIG. 7 shows graphs of contact resistance as a function of storage time, with FIG. 7a showing data for prior art contacts and FIG. 7b showing data for contacts in accordance with an embodiment of the invention.

### DETAILED DESCRIPTION

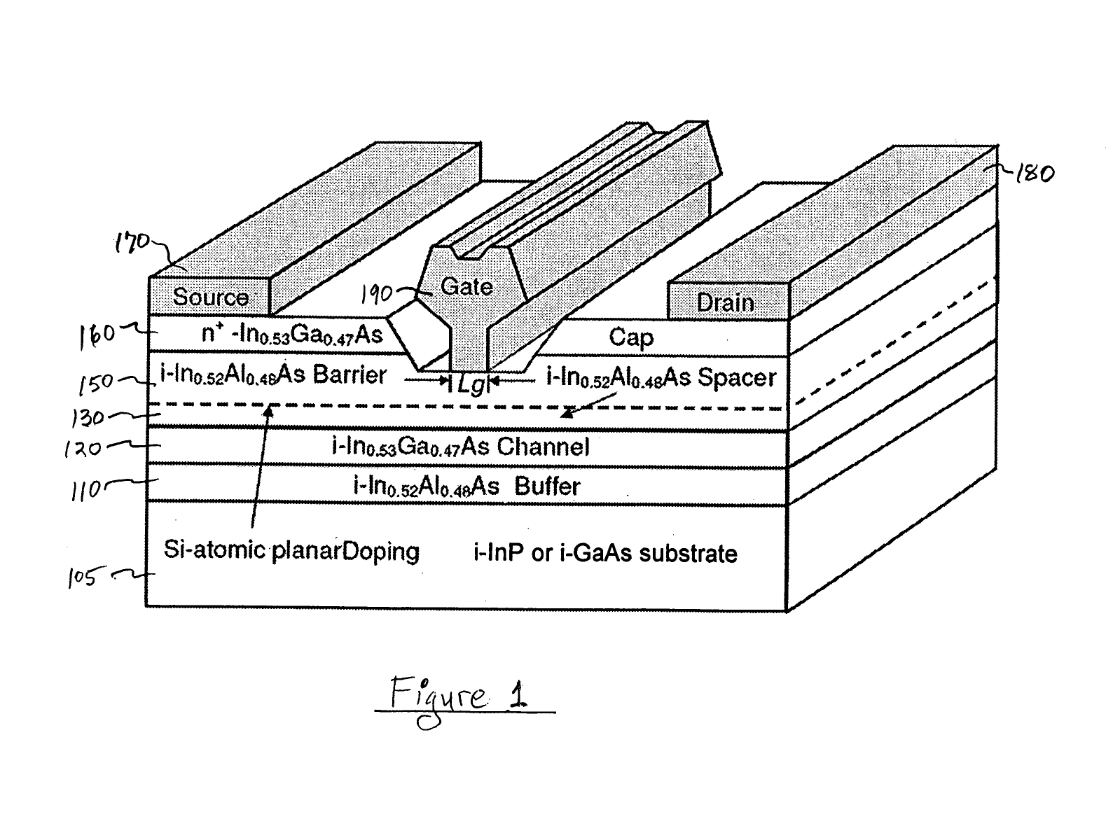

Referring to FIG. 1, there is shown, in cross-section, an example of a type of device which can be made in accordance with an embodiment of the invention. The device of FIG. 1 is a high electron mobility transistor (HEMT), which, in this example, is a field-effect HEMT formed on an indium phosphide substrate or gallium arsenide substrate 105 (therefore commonly called an InP HEMT or GaAs metamorphic HEMT) on which is deposited an insulating In_{0.52}Al_{0.48}As buffer layer. In this diagram, there is shown an undoped In_{0.53}Ga_{0.47}As channel layer 120, and, over this layer, a spacer layer 130 of undoped In_{0.52}Al_{0.48}As, a thin Si-atomic planar doping region, and an undoped In_{0.52}Al_{0.48}As barrier layer 150, and, except in the notched central region, a heavily doped n-type In_{0.53}Ga_{0.47}As cap layer 160. Spaced apart source 170 and drain 180 contacts are formed on the n+In_{0.53}Ga_{0.47}As cap layer 160, and the gate 190, which is shown as a T-gate in this example, is formed with a Schottky barrier contact of length L_{g} on the In_{0.52}Al_{0.48}As barrier layer 150. As will be described, the source and drain contacts are ohmic contacts formed in accordance with embodiments of the invention.

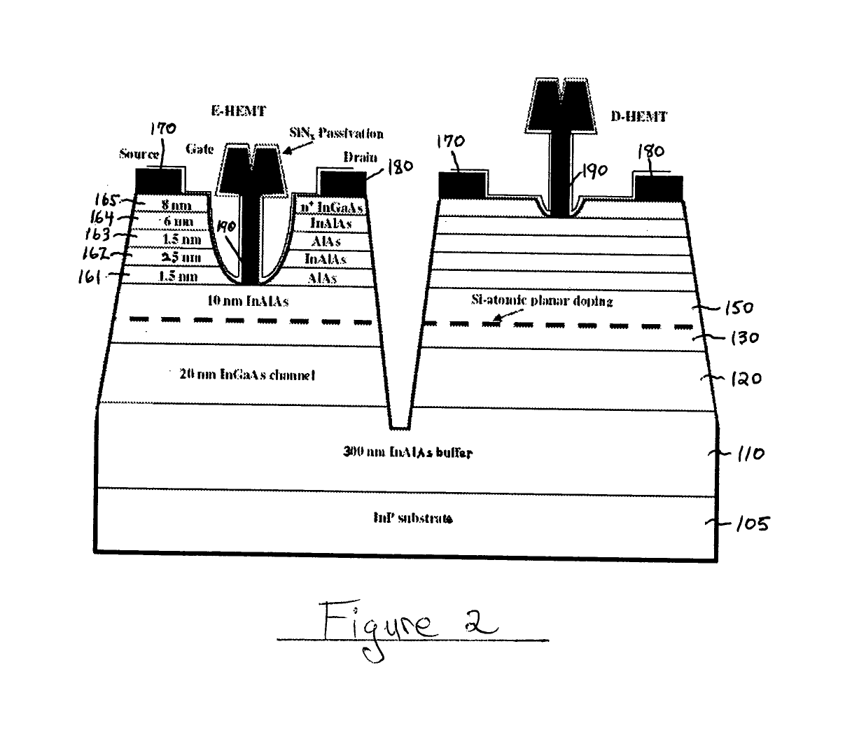

The HEMT structure of an example hereof was designed for two different recess etching depths in order to achieve the integration of enchancement- and depletion-mode (E/D) HEMT devices (see A. Mahajan et al. 1998, supra). In this regard, reference can be made to the diagram of FIG. 2, which shows, on the left, the enhancement mode device, and, on the right, the depletion mode device, of the integrated structure. The layers 105, 110, 120, 130, and 150 are similar to their counterparts in FIG. 1. The heterostructure used in this example was grown by molecular beam epitaxy on a (100) semi-insulating InP substrate (105) and it included of a 300 nm-thick undoped In_{0.52}Al_{0.48}As buffer layer (110), a 20 nm-thick undoped In_{0.53}Ga_{0.47}As channel layer (120), a 4 nm-thick undoped In_{0.52}Al_{0.48}As spacer layer (130), a Si planar-doped layer with a sheet carrier concentration of 3.84×10¹² cm⁻², a 6 nm thick undoped In_{0.52}Al_{0.48}As barrier layer (150), a 2.5 nm-thick AlAs first etch stop layer (161), a 3.5 nm-thick undoped In_{0.52}Al_{0.48}As first barrier layer (162), an AlAs second etch stop layer (163), an InAlAs second barrier layer (164) and an 8 nm-thick heavily Si-doped n-In_{0.53}Ga_{0.47}As contact layer (165). The heterostructure was designed for the realization of depletion and enchancement-mode HEMTs.

Regarding the contact metallizations as for source and drain, mesa isolation was first performed using a mixture of citric acid and hydrogen peroxide. Then, linear transmission line method (TLM) patterns were defined by photolithography. Metallization including AuGe/Ni/Au (˜60/10/60 nm), AuGe/Ni (˜60/10 nm), and Ge/Ag/Ni (60/40/24 nm) were prepared using thermal or electron beam evaporation and lift-off techniques with AuGe and Ge in contact with the semiconductor, respectively. The AuGe used was the eutectic alloy with 88% Au and 12% Ge by weight. Annealing was performed for 30 s at temperatures ranging from 200 to 450° C. in a rapid thermal annealing (RTA) system.

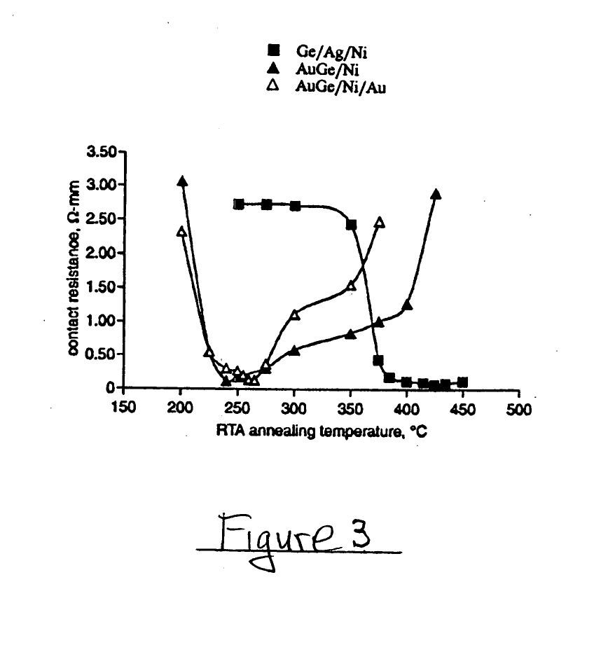

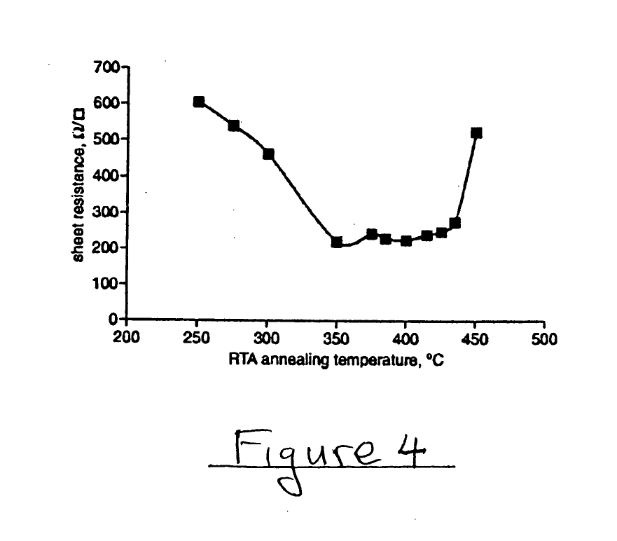

After annealing, the electrical characteristics were measured using an Agilent 4142B parameter analyzer. As deposited, all three metallizations showed non-ohmic characteristics. As shown in FIG. 3, the minimum contact resistances for both AuGe/Ni/Au and AuGe/Ni metallizations were obtained at annealing temperatures around 250° C. However, an annealing temperature of about 400° C. was necessary to achieve low contact resistance for the Ge/Ag/Ni metallization with a minimum contact resistance of 0.07 Ω-mm obtained at a temperature of 425° C. Contact resistances of less than 0.2 Ω-mm are usually required for high performance HEMT applications. This gives an annealing temperature window of only 10-15° C. for the metallization based on AuGe, which makes the process relatively sensitive. On the other hand, for the Ge/Ag/Ni metallization, low contact resistances were obtained for temperatures ranging from 385 to 450° C., resulting in a larger processing latitude. The contact resistances at 385 and 450° C. were 0.18 and 0.12 Ω-mm, respectively. FIG. 4 shows the sheet resistance measured from the same TLM patterns. Before ohmic contact formation, the sheet resistances measured were relatively high due to measurement errors. At temperatures higher than 435° C., the sheet resistance increased rapidly, which may have been due to the out diffusion of the As component in the HEMT structure. Surface roughness of the annealed samples was measured on the 10 μm gap of the TLM patterns by atomic force microscopy (AFM). The root mean square (rms) roughness values of the samples annealed at temperatures above 435° C. were ˜0.76 nm, which is not significantly higher than the 0.5 nm obtained prior to annealing. Therefore, based on this example, the practical temperatures for annealing the Ge/Ag/Ni contact are in the range from 385 to 435° C.

In the next example there is set forth a method to broaden the thermal processing latitude by passivating the silver-based contacts using a thin layer of SiNₓ during annealing. Si₃N₄ can also be utilized for passivation. Also in this example, thermal storage tests demonstrate the long-term thermal stability of Ge/Ag/Ni ohmic contact with an overlay of Ti/Pt/Au in comparison with annealed-AuGe/Ni ohmic contact. The fabrication of depletion-mode InP-based HEMT's with Ge/Ag/Ni ohmic contacts is also demonstrated.

The heterostructure used for this example was the same as that used for the prior example. The sheet resistance, sheet carrier concentration and electron mobility of the heterolayer were 225 Ω/□, 3.84×10¹² cm⁻², and 7210 cm⁻²/V₋ₛ, respectively, as determined by Hall measurements. The linear transmission line method (TLM) was again utilized to evaluate the ohmic contact properties. As before, to fabricate the TLM patterns, mesa isolation was first performed using a citric acid/hydrogen peroxide solution. Then the TLM patterns were defined by photolithography and Ge/Ag/Ni (60/40/24 nm) metallization was deposited using electron beam evaporation and lift-off techniques with Ge in contact with the semiconductor. SiNₓ layer was deposited using the PECVD method at a substrate temperature of 300° C. The samples were then annealed in a RTA system at various temperature and durations in a N₂ ambient. The electrical characteristics of the contacts were measured using an Agilent 4142B semiconductor parameter analyzer. Thermal storage tests were conducted by measuring ohmic contact values at intervals between thermal treatments in a furnace with a N₂ ambient. The Ge/Ag/Ni contacts were compared with AuGe/Ni contacts that were formed at 245° C. in a RTA system.

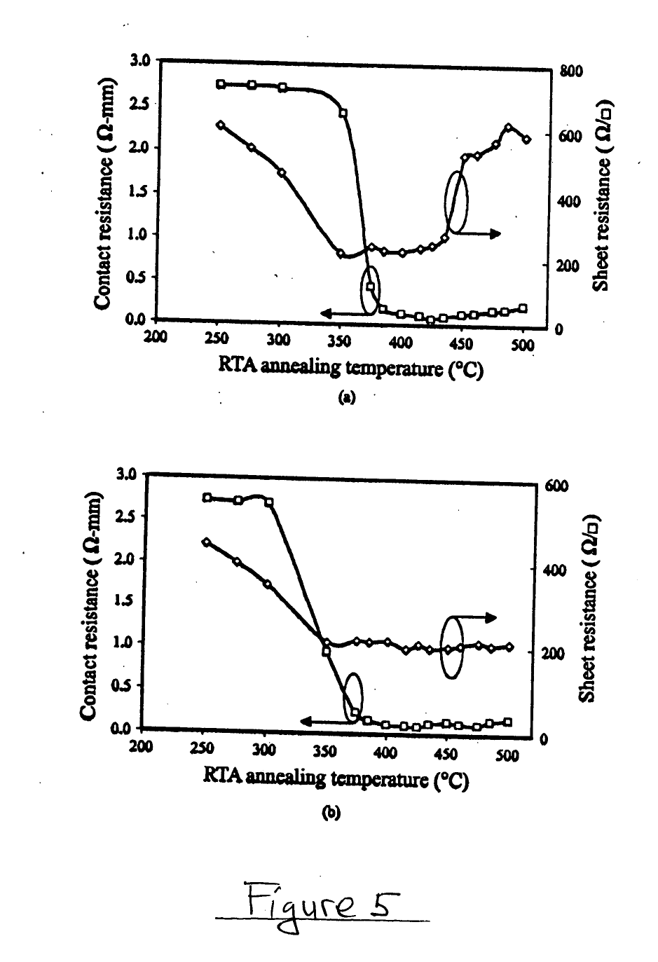

FIG. 5 shows the contact resistance and sheet resistance of Ge/Ag/Ni metallization as functions of annealing temperature: (a) without SiNₓ passivation layer during annealing, and (b) with a 60-nm-thick SiNₓ passivation layer during annealing. Annealing time was fixed at 30 s in both cases. At temperatures below 350° C., sheet resistance values were inconsistent with the value of 225 Ω/□ obtained by Hall measurements, indicating that it is invalid to use TLM patterns to extract sheet resistance before ohmic formation. At temperatures above 435° C., the sheet resistance of the samples without SiNₓ passivation layer degraded rapidly to values as high as −600 Ω/□ as shown in FIG. 5(a). FIG. 5(b) shows that a 60-nm-thick SiNₓ layer had successfully suppressed sheet resistance degradation, and the sheet resistance values were maintained at ˜200 Ω/□ for temperatures up to 500° C. The SiNₓ layer also passivated the heteostructure surface, thus the sheet resistances were lower compared with that of the virgin sample obtained by Hall measurements. Ashizawa et al. (Solid State Electron., Vol. 38, No. 9, pp. 1627-1630, 1995) attributed the degradation of the InAlAs/InGaAs/InP HEMT structure during thermal stress to the deterioration of the crystalline quality of the InAlAs layers due to outdiffusion of In and As. In Ashizawa et al., 1995, supra, a 100-nm-thick SiNₓ passivation layer was shown to be effective in suppressing the degradation of the carrier concentration and electron mobility of HEMT layers.

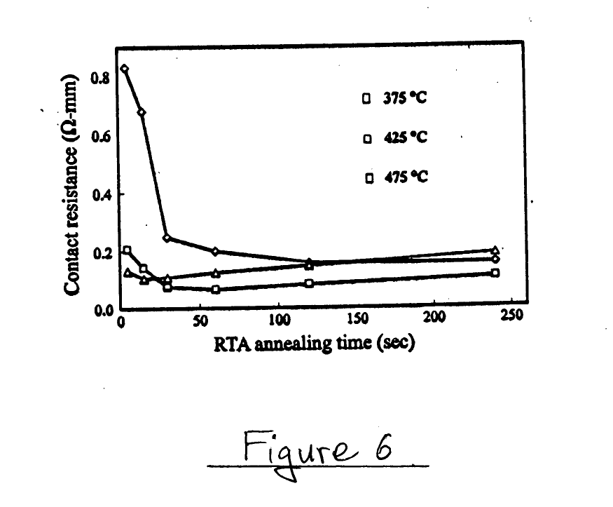

Contact resistances of the Ge/Ag/Ni metallization as a function of annealing time at different temperatures are shown in FIG. 6. All samples were passivated with a 60-nm-thick SiNₓ layer before annealing. For the annealing temperature of 375° C., an annealing time of 2 min was required to obtain good ohmic contacts and the ohmic characteristic obtained was improved as a function of annealing time as shown in the Figure. For 425° C., the best contact resistance obtained was 0.06 Ω·mm for an annealing time of 60 s with a specific contact resistivity of 2.62×10⁻⁷ Ω·cm². The contact resistance values were under 0.11 Ω·mm for annealing durations up to 4 min. When the samples were annealed at 475° C., an annealing of 5 s was sufficient to obtain a contact resistance of 0.10 Ω·mm, and thereafter, it degraded gradually. However, it should be noted that this was a slight degradation with a contact resistance of 0.18 Ω·mm recorded for a 4-min anneal. As observed, the best contact resistances obtained at different temperatures were slightly different. This implies that some complex reactions between the metals and the heterolayers are involved in the process of ohmic formation.

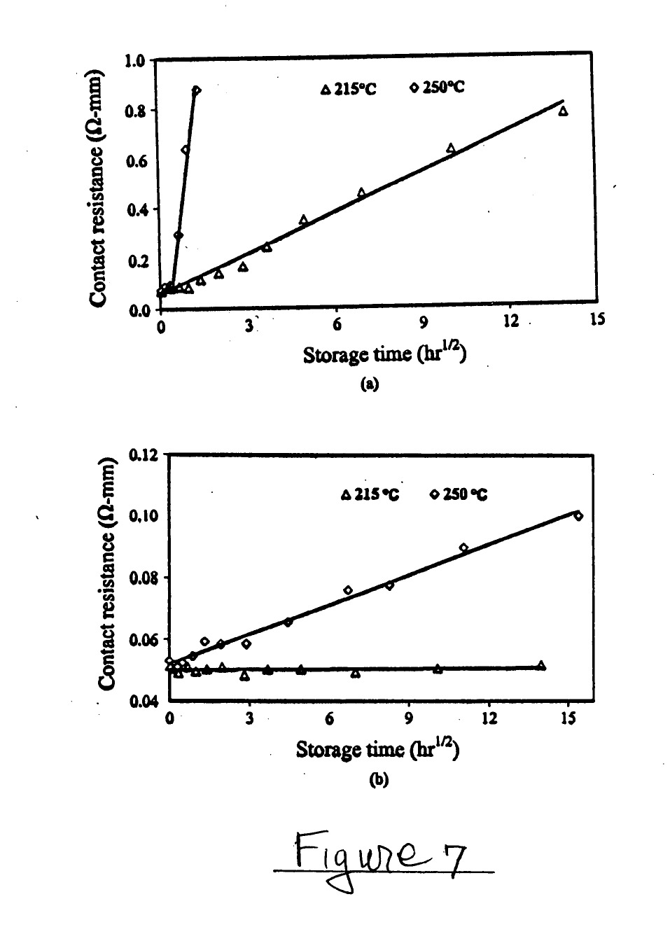

Long-term thermal stability of the Ge/Ag/Ni ohmic contact with an overlay of Ti/Pt/Au was studied by thermal storage test at 215 and 250° C. in a N₂ ambient. Before the storage test, samples with Ge/Ag/Ni TLM patterns were annealed at 425° C. for 60 s with a SiNₓ passivation layer to obtain the best ohmic contact characteristics. Then, a second level of TLM pattern with slightly larger gap spacings was defined on top of the Ge/Ag/Ni TLM pattern by photolithography. Before the evaporation of Ti/Pt/Au (15/15/170 nm) overlay, the sample was dipped in buffered oxide etch (BOE) for about 60 s to remove the SiNₓ passivation layer on top of the contacts, so that the Ti/Pt/Au layer was in direct contact with the ohmic metal. Due to the slightly larger gap spacing of the overlay TLM patterns compared with that of the Ge/Ag/Ni TLM patterns, the gaps and edges of the contacts remain passivated with SiNₓ. For comparison, samples with conventional ohmic metallization of AuGe/Ni (unpassivated and formed at 245° C. for 30 s with a contact resistance of 0.07 Ω·mm) with an overlay of Ti/Pt/Au were investigated together with the Ge/Ag/Ni samples. Samples were thermally treated and taken out for electrical measurements intermittently. For the AuGe/Ni ohmic contacts, the contact resistance doubled within a 10-h period during the storage test at 215° C.; and at 250° C., it doubled within a period of <1 h as shown in FIG. 7(a).

The rapid increase of contact resistances for the AuGe/Ni ohmic metallization demonstrated that its thermal stability was rather poor. It is noted that the passivation of the AuGe/Ni ohmic contact with a 60-nm-thick layer of SiNₓ during storage test did not improve its thermal stability at these two temperatures. It was observed that the degradation rate of the annealed AuGe/Ni ohmic contact depended on the heterostructure, i.e., the thinner the total thickness of the layers above the two-dimensional electron gas (2 DEG), the higher the degradation rate. A much improved thermal stability for Ge/Ag/Ni ohmic contacts was obtained as shown in FIG. 7(b). At 215° C., Ge/Ag/Ni contacts showed no degradation after 200 h; and at 250° C., the contact resistance only increased to a value of 0.1 Ω·mm after a 250-h period. For both AuGe/Ni and Ge/Ag/Ni ohmic contacts, the linear dependence of contact resistance on the square root of storage time suggests that the degradation of the contact resistance was caused by the diffusion or interdiffusion of elements from or between the contact metallizations and the epitaxial layers.

Depletion-mode HEMTs (D-HEMTs) using Ge/Ag/Ni ohmic contacts and SiNₓ passivation with Ti/Pt/Au overlay were fabricated. The contacts were annealed at 425° C. with a resulting contact resistance of 0.06 Ω·mm. The devices had T-gates with a gate length of 0.2 μm DC measurements on the devices showed a typical peak transconductance (G_{m,max}) of 835 mS/mm and a maximum drain current (I_{D,max}) of 813 mA/mm (for V_{GS}=0.7V, V_{DS}=2.0V). The unity current gain frequency (f_{T}) and maximum frequency of oscillation (fₘₐₓ) were 156 and 245 Ghz, respectively, as determined using an HP 8510C measurement system. These values were virtually identical to those obtained for D-HEMTs fabricated using AuGe/Ni ohmic contacts on the same heterostructure. These were G_{m,max}=847 mS/mm, I_{D,max}=802 mA/mm, f_{T}=159 GHz, and fₘₐₓ=250 GHz. The D-HEMT's with the Ge/Ag/Ni metallization are expected to be thermally more stable, due to the superior thermal stability of their ohmic contact characteristics, as demonstrated hereinabove.

1. A field-effect device, comprising:
a layered semiconductor structure that includes a channel layer and at least one layer over the channel layer, said at least one layer including an InGaAs cap layer;
spaced apart source and drain ohmic contacts disposed on said InGaAs cap layer, said source and drain contacts comprising silver-based contacts deposited on said InGaAs cap layer; and
a gate contact, between said source and drain contacts, disposed on said at least one layer.

2. The field-effect device as defined by claim 1, wherein said silver-based source and drain ohmic contacts include deposited layers of germanium, silver, and nickel, thereby comprising Ge/Ag/Ni ohmic contacts.

3. The field-effect device as defined by claim 2, further comprising a metallic overlay deposited over each of said Ge/Ag/Ni source and drain ohmic contacts.

4. The field-effect device as defined by claim 3, wherein said metallic overlay comprises Ti/Pt/Au.

5. The field-effect device as defined by claim 1, further comprising means for applying electrical potentials with respect to said drain, source, and gate contacts.

6. A method of forming an ohmic contact to a III-V semiconductor material, comprising the steps of:
depositing a silver-based contact on said semiconductor material; and
annealing the silver-based contact at a temperature greater than about 350° C. to form an ohmic contact on said semiconductor material.

7. The method as defined by claim 6, wherein said annealing is performed at a temperature of about 400° C.

8. The method as defined by claim 6, wherein said III-V semiconductor material is an indium-containing compound.

9. The method as defined by claim 6, wherein said silver-based contact is a Ge/Ag/Ni contact.

10. A method of forming an ohmic contact to InGaAs semiconductor material, comprising the steps of:
depositing a Ge/Ag/Ni contact on said semiconductor material; and
annealing the Ge/Ag/Ni contact at a temperature greater than about 350° C. to form an ohmic contact on said semiconductor material.

11. The method as defined by claim 10, wherein said annealing is performed at a temperature of about 400° C.

12. The method as defined by claim 10, further comprising passivating said contacts, prior to annealing, with Si₃N₄ or SiNₓ.

13. The method as defined by claim 10, further comprising depositing a metallic overlay over said Ge/Ag/Ni contact.

14. The method as defined by claim 12, further comprising depositing a metallic overlay over said Ge/Ag/Ni contact.

15. The method as defined by claim 13, wherein said step of depositing a metallic overlay over said Ge/Ag/Ni contact comprises depositing a Ti/Pt/Au overlay.

16. A high electron mobility field-effect transistor device, comprising:
a layered semiconductor structure that includes an InGaAs channel layer and at least two layers over the channel layer, said at least two layers including a layer of InAlAs, a portion of which has an InGaAs cap layer deposited thereon;
spaced apart source and drain ohmic contacts disposed on said InGaAs cap layer, said source and drain contacts comprising silver-based contacts deposited on said InGaAs cap layer; and
a gate contact, between said source and drain contacts, disposed on said InAlAs layer.

17. The device as defined by claim 16, wherein said silver-based source and drain ohmic contacts include deposited layers of germanium, silver, and nickel, thereby comprising Ge/Ag/Ni ohmic contacts.

18. The device as defined by claim 17, comprising a metallic overlay deposited over each of said Ge/Ag/Ni source and drain ohmic contacts.

19. The device as defined by claim 18, wherein said metallic overlay comprises Ti/Pt/Au.

20. The device as defined by any of claim 16, further comprising means for applying electrical potentials with respect to said drain, source, and gate contacts.

21. A method of making a high electron mobility field-effect transistor device, comprising the steps of:
providing a layered semiconductor structure that includes an InGaAs channel layer and at least two layers over the channel layer, said at least two layers including a layer of InAlAs, a portion of which has an InGaAs cap layer deposited thereon;
depositing spaced apart source and drain ohmic contacts on said InGaAs cap layer, said source and drain contacts comprising Ge/Ag/Ni contacts; and
depositing a gate contact, between said source and drain contacts, on said InAlAs layer.

22. The method as defined by claim 21, wherein said step of depositing Ge/Ag/Ni contacts on said InGaAs cap layer comprises annealing the Ge/Ag/Ni contacts at a temperature greater than about 350° C. to form an ohmic contact on said InGaAs cap layer.

23. The method as defined by claim 22, wherein said annealing is performed at a temperature of about 400° C.

24. The method as defined by claim 22, further comprising passivating said contacts, prior to annealing, with Si₃N₄ or SiNₓ.

25. The method as defined by claim 22, further comprising depositing a metallic overlay over said Ge/Ag/Ni contact.

26. The method as defined by claim 24, further comprising depositing a metallic overlay over said Ge/Ag/Ni contact.

27. The method as defined by claim 25, wherein said step of depositing a metallic overlay over said Ge/Ag/Ni contact comprises depositing a Ti/Pt/Au overlay.
